(19) United States
(12) Patent Application Publication
(10) Pub. No.: US 2014/0357072 A1
(43) Pub. Date: Dec. 4, 2014

(54) METHODS AND STRUCTURES FOR SPLIT GATE MEMORY

(71) Applicants: JINMIAO J. SHEN, Austin, TX (US); Sung-Taeg Kang, Austin, TX (US); Brian A. Winstead, Austin, TX (US)

(72) Inventors: JINMIAO J. SHEN, Austin, TX (US); Sung-Taeg Kang, Austin, TX (US); Brian A. Winstead, Austin, TX (US)

(21) Appl. No.: 13/907,845

(22) Filed: May 31, 2013

(51) Int. Cl. H01L 21/28

(52) U.S. Cl. CPC H01L 21/28282
USPC 438/591

(57) ABSTRACT

A method of making a non-volatile memory (NVM) cell using a substrate having a top surface of silicon includes forming a select gate stack over the substrate. An oxide layer is grown on the top surface of the substrate. Nanocrystals of silicon are formed on the thermal oxide layer adjacent to a first side the select gate stack. The nanocrystals are partially oxidized to result in partially oxidized nanocrystals and further growing the thermal oxide layer. A control gate is formed over the partially oxidized nanocrystals. A first doped region is formed in the substrate adjacent to a first side of the control gate and a second doped region in the substrate adjacent to a second side of the select gate.

### BACKGROUND

1. Field

This disclosure relates generally to semiconductor devices, and more specifically, to split gate memory cells.

2. Related Art

Split gate devices, which include both a select gate and a control gate, are typically used as bitcell storage devices within nonvolatile memory arrays. The use of a separate select gate for the bitcells in such arrays allows for improved isolation and reduced bitcell disturb during programming and reading of the bitcells. Split gate non-volatile memories (NVMs) including, for example, split gate flash devices, provide advantages such as low power and space requirements, over stacked-gated devices. Split gate thin film storage memory cells include a layer of discrete charge storage elements embedded between dielectric layers. Charge is stored in the discrete storage elements (also referred to as nanocrystals) when the memory cell is programmed. It is desirable to find ways to improve the performance of split-gate memory cells for faster erase, faster programming and better gate length scaling particularly when the memory devices may be subject to high temperature and high endurance requirements.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIGS. 1-6 show a cross-sectional view of an embodiment of a split gate memory cell during successive stages of manufacture.

FIG. 7 shows a cross sectional side view of another embodiment of a memory cell.

FIG. 8 shows a cross sectional side view of charge storage elements before and after oxidation.

### DETAILED DESCRIPTION

Embodiments of methods and semiconductor devices disclosed herein provide a split gate memory cell for a memory device that replaces chemical vapor deposited (CVD) oxide layer over the charge storage elements with larger charge storage elements that are placed closer together and then thermally oxidized to form a thermal dielectric layer over the charge storage elements. The thermal dielectric layer grown from the charge storage elements provides a higher quality oxide that resists damage due to hot electron injection and tunneling during program and erase operations to a greater extent than CVD oxide. The thermal dielectric layer grown from the charge storage elements also enables use of a thinner top oxide than previously known split gate structures, providing higher transconductance, faster erase and programming performance, and enables the use of smaller gate lengths than previously known split gate structures.

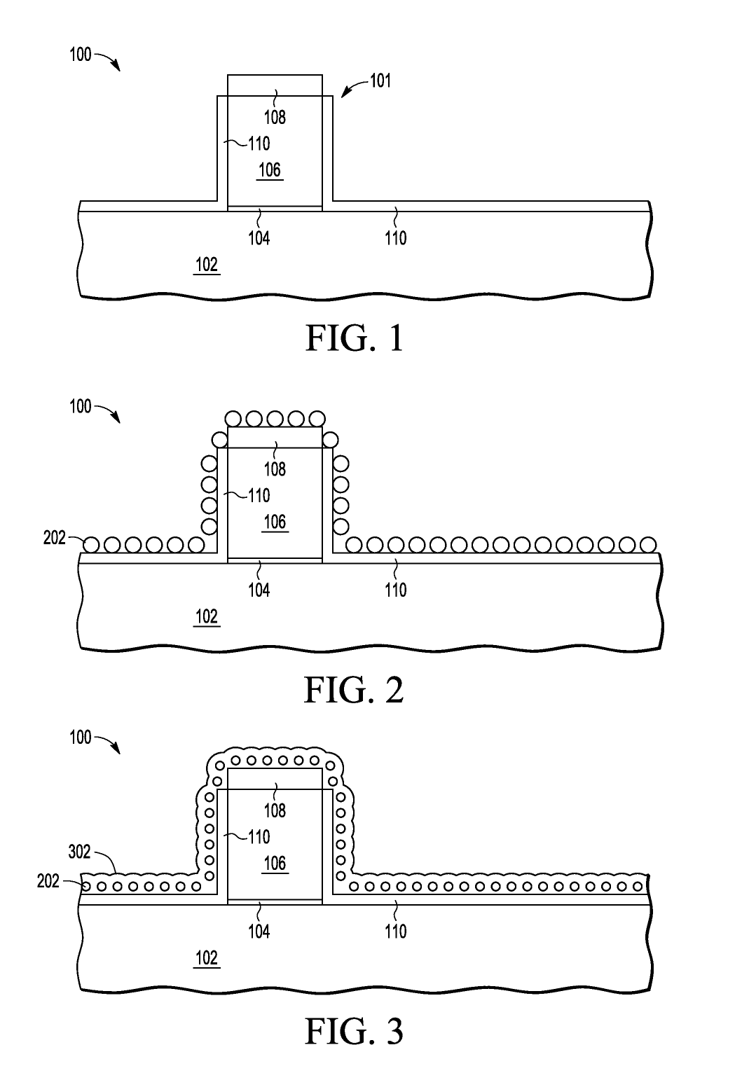

FIG. 1 shows a cross-sectional view of a portion of an embodiment of a memory cell 100 such as a split gate memory cell after an intermediate stage of manufacture in which a select gate structure 101 has been formed on substrate 102 including gate dielectric layer 104, select gate layer 106, nitride layer 108 on select gate layer 106, and bottom dielectric layer (also referred to as tunnel oxide layer) 110 over exposed portions of substrate 102 and sidewalls of gate dielectric layer 104 and select gate layer 106. Bottom dielectric layer 110 has a different etch selectivity than select gate 106.

Semiconductor substrate 102 described herein can be any semiconductor material or combinations of materials, such as gallium arsenide, silicon germanium, silicon-on-insulator (SOI), silicon, monocrystalline silicon, the like, and combinations of the above. Semiconductor substrate 102 may also be referred to as a semiconductor layer. Gate dielectric layer 104 is next to substrate 102. Select gate layer 106 is formed over the gate dielectric layer 104. Gate dielectric layer 104 may be any appropriate gate dielectric layer, such as, for example, a gate oxide layer. Select gate layer 106 may be a polysilicon gate layer. Alternatively, select gate layer 106 may also be a metal, titanium nitride, or a combination of materials. Select gate layer 106 can be formed using one or more dry etch steps such as a breakthrough etch of an anti-reflective coating and a main etch which etches through the material of select gate layer 106 (such as, for example, carbon fluoride, in the case that select gate layer 106 is polysilicon), the etch chemistry may also include an oxidizing agent. The oxidizing agent may include for example, oxygen (O₂) or helium oxide (HeO₂).

FIG. 2 shows a cross-sectional view of memory cell 100 after a subsequent stage of manufacture in which discrete charge storage elements 202 are deposited or formed on bottom dielectric layer 110, nitride layer 108, and the sidewalls of select gate structure 101 (FIG. 1). Charge storage elements 202 can be silicon nitride, silicon oxynitride or other suitable material and are also referred to as nanocrystals. In some embodiments, charge storage elements 202 have a median diameter of approximately 16 nanometers and are spaced from each other on average at a distance that is less than or equal to the thickness of bottom dielectric layer 110. For example, the thickness of the bottom dielectric layer 110 may be 6 nanometers and the space between charge storage elements 202 may be 2 nanometers or less. Other suitable dimensions for charge storage elements 202 and bottom dielectric layer 110, and the distance between charge storage elements 202, can be used.

Conventional processing may be used to form charge storage elements 202. Charge storage elements 202 may include any type of conductive material that oxidizes from the outside in at elevated temperatures, such as, for example, silicon, or the like. An inner portion of the charge storage elements 202 will remain unoxidized when subjected to elevated temperature for a limited duration of time, as further described herein.

FIG. 3 shows a cross-sectional view of memory cell 100 after a subsequent stage of manufacture in which top dielectric layer 302 is formed over and surrounding charge storage elements 202 by oxidizing an outer portion of charge storage elements 202. The outer portion of charge storage elements 202 can be formed by exposing memory cell 100 to an elevated temperature for a specified duration of time in an ambient environment of particular gas or gases. For example, the oxidation may occur at temperature ranging from 800 C to 1150 C for 15 seconds to 5 minutes in an oxygen-rich environment, such as O₂ only, H₂:O₂, or N₂O:H₂. Other suitable temperature ranges, durations, and ambient environments can be used.

At the end of the specified duration of time, top dielectric layer 302 has a thickness that is greater or equal to than the thickness of bottom dielectric layer 110. The distance between the unoxidized portion of the outer surface of adjacent charge storage elements 202 is greater than or equal to the thickness of bottom dielectric layer 110. For example, in some embodiments, the remaining unoxidized portion of charge storage elements 202 has a total thickness or diameter of approximately 12 nanometers and the distance between the unoxidized portion of the outer surface of adjacent charge storage elements 202 is greater than or equal to 6 nanometers. Top dielectric layer 302 forms a continuous conformal layer over charge storage elements 202.

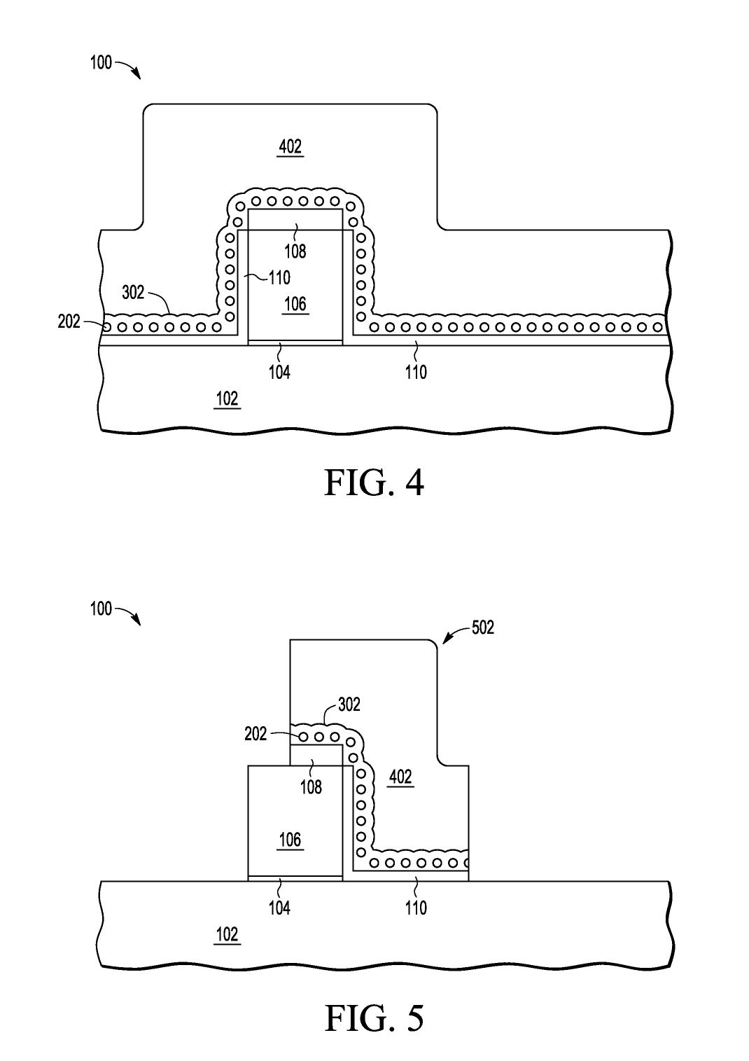

FIG. 4 shows a cross-sectional view of memory cell 100 after a subsequent stage of manufacture in which conductive material 402 for forming a control gate is deposited over top dielectric layer 302. Material 402 may include polysilicon, a metal, titanium nitride, etc., or combinations thereof and can be formed using conventional deposition techniques such as by depositing a conformal layer of polysilicon material. The conformal layer is either conductive or able to become conductive. In the case of polysilicon, the material 404 is doped in order to be more conductive. The doping typically occurs by implants after deposition but could be by in situ doping or a combination of in situ doping and subsequent implants. The thickness of control gate 402 is typically less than the thickness of select gate 106.

FIG. 5 shows a cross-sectional view of memory cell 100 after a subsequent stage of manufacture in which a portion of conductive material 402 is removed to form control gate 502 to a sidewall of the select gate structure 101 (FIG. 1) and over a portion of substrate 102. In some embodiments, a portion of nitride layer 108 is removed using a dry etch such that a portion of nitride layer 108 remains between control gate 502 and select gate structure 101. An anisotropic etch is performed to remove portions of conductive material 402, dielectric layers 110, 302, and charge storage elements 202, such that a portion of charge storage elements 202, and dielectric layers 110, 302 remains between control gate 502 and select gate structure 101 and between control gate 502 and substrate 102. In the vertical direction, the height of the remaining portion of charge storage elements 202 and dielectric layers 110, 302 is less than the height of control gate 502 after the etch process. In the horizontal direction, the width of the remaining portion of charge storage elements 202 and dielectric layers 110, 302 is less than or equal to the width of control gate 502 after the etch process.

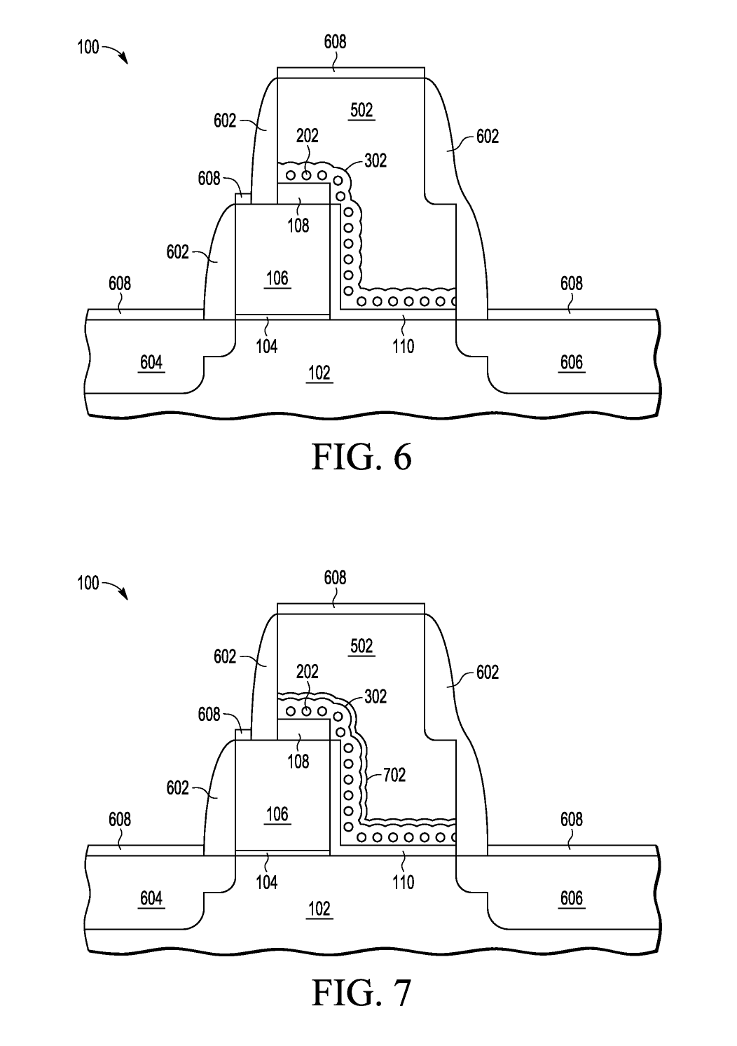

FIG. 6 shows a cross-sectional view of split gate memory cell 100 during a subsequent stage of manufacture in which implant processes using conventional ion implant can be performed to form drain region 604 in substrate 102 adjacent a portion of select gate 106 and source region 606 in substrate 102 adjacent a portion of control gate 502.

Spacers 602 are formed on exposed sidewalls of select gate 106 and control gate 502 by a conventional process of depositing nitride and performing an anisotropic etch. Deep well implants can be performed to increase the depth of drain region 604 and source region 606.

Silicide contacts 608 are formed on the exposed surface of each of the source region 604, the drain region 606, the control gate 502 and the select gate 106 to enable electrical contact to be made to memory cell 100. In particular, a first silicide contact 608 is formed at an upper surface of source region 604 for making electrical contact to source region 604. A second silicide contact 608 is formed at an upper surface of drain region 606 for making electrical contact to drain region 606. A third silicide contact 608 is formed at an upper surface of select gate 106 for making electrical contact to select gate 106. A fourth silicide contact 608 is formed at an upper surface of the control gate 502 for making electrical contact to the control gate 502.

FIG. 7 shows a cross-sectional view of another embodiment of a split gate memory cell 700 in which oxide layer 702 is deposited over top dielectric layer 302 to add another layer of insulation over top dielectric layer 302. In some embodiments, oxide layer 702 can be high temperature oxide (HTO) or an oxynitride. Oxide layer 702 can be annealed in a gas such as NO, N2O, O2 or N2 gas at 800-1000 degrees Centigrade, for example. In some embodiments, the thickness of oxide layer can range from 40-80 Angstroms, however, other suitable thicknesses can be used. Oxide layer 702 is electrically nonconductive.

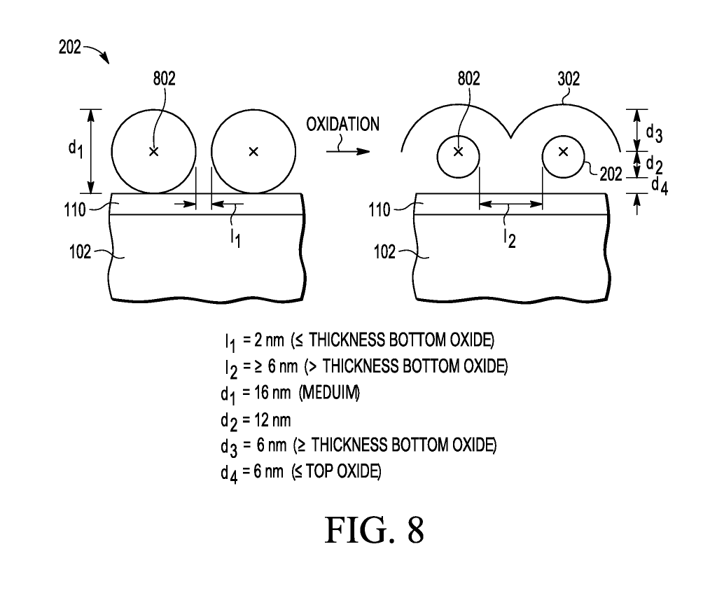

FIG. 8 shows a cross sectional side view of two adjacent charge storage elements 202 before and after oxidation. In the unoxidized state shown on the left side of FIG. 8, charge storage elements 202 are approximately round with an average or median diameter d1 and center point 802 in the middle of charge storage elements 202. The diameter of charge storage elements 202 may vary within a certain standard deviation. After oxidation as shown on the right side of FIG. 8, the median diameter of charge storage elements 202 has been reduced to median diameter d2 and top dielectric layer 302 has formed around the reduced circumference of charge storage elements 202 from an outer portion of charge storage elements 202. Note that the amount or thickness of top dielectric layer 302 adjacent bottom dielectric layer 110 (shown as d4) is less than the amount or thickness of top dielectric layer 302 above charge storage elements 202 (shown as d3). Additionally, top dielectric layer 302 converges between adjacent charge storage elements 202 to form a contiguous layer. To avoid electron tunneling between adjacent charge storage elements 202, the distance I2 between adjacent charge storage elements 202 is greater than the thickness of the combination of bottom dielectric layer 110 and the portion of top dielectric layer 302 that forms adjacent bottom dielectric layer 110.

In some embodiments, the thickness d3 of top dielectric layer 302 is greater than or equal to the thickness of bottom dielectric layer 110. Accordingly, point 802 is now offset from the center of charge storage elements 202 because charge storage elements 202 do not oxidize evenly around the circumference due to insulating effects of bottom dielectric layer 110. The distance 12 between the outer surface of adjacent charge storage elements 202 increases after oxidation. The shape of charge storage elements 202 may include a flattened portion on top and sides while the bottom of charge storage elements 202 may be round.

Charge storage elements 202 are initially formed with a large diameter or thickness and high density so that charge storage elements 202 are still capable of retaining data for the target duration even after oxidation of the outer layer of charge storage elements 202. The top dielectric layer 302 formed by thermal oxidation is high quality and relatively thin compared to CVD dielectric formed by deposition and anneal. The relatively thin top dielectric layer 302 improves transconductance, erase speed, program speed, and gate length scaling of memory cell 100 (FIG. 6).

By now it should be appreciated that in some embodiments, a method of making a non-volatile memory (NVM) cell (100) using a substrate (102) having a top surface of silicon, can comprise forming a select gate stack (101) over the substrate; growing a thermal oxide layer (110) on the top surface of the substrate; forming nanocrystals (202) of silicon on the thermal oxide layer adjacent to a first side of the select gate stack; partially oxidizing the nanocrystals to result in partially oxidized nanocrystals and further growing the thermal oxide layer; forming a control gate (402) over the partially oxidized nanocrystals; and forming a first doped region (606) in the substrate adjacent to a first side of the control gate and a second doped region (604) in the substrate adjacent to a second side of the select gate.

In another aspect, the step of forming the select gate stack can be further characterized by the select gate stack comprising polysilicon.

In another aspect, the step of growing the thermal oxide layer can be further characterizing as growing the thermal oxide on the polysilicon on the first side of the select gate.

In another aspect, the step of forming the nanocrystals can be further characterized by forming nanocrystals on the thermal oxide on the first side of the select gate.

In another aspect, the method can further comprise forming sidewall spacers adjacent to the second side of the select gate and the first side of the control gate.

In another aspect, the step of forming the control gate can be further characterized by the control gate being deposited directly on the partially oxidized nanocrystals.

In another aspect, the step of forming the control gate can be further characterized by the control gate comprising polysilicon.

In another aspect, the method can further comprise depositing a dielectric layer (702) on the partially oxidized nanocrystals prior to forming the control gate, wherein the forming the control gate is further characterized by being over the dielectric layer.

In another aspect, the step of forming the control gate can comprise depositing a conductive layer (402 FIG. 4) over the partially oxidized nanocrystals; and patterning the conductive layer to form the first side of the control gate and to form a second side of the control gate over the select gate.

In another aspect, the step of forming the nanocrystals can be further characterized by the nanocrystals having a median original diameter; and the step of partially oxidizing the nanocrystals can result in a reduction from the median original diameter of about one fourth.

In another aspect, the step of forming the nanocrystals can be further characterized by the median original diameter being about 16 nanometers.

In another aspect, the step of partially oxidizing the nanocrystals can result in sufficient oxide growth that the oxide growth of adjacent nanocrystals merges.

In other embodiments, a method of forming a non-volatile memory (NVM) structure (100) on a substrate (102) having a silicon surface, can comprise growing an oxide layer (110) on the silicon surface; forming silicon nanocrystals (202) on the oxide layer; partially growing oxide on the nanocrystals (302); and forming a control gate (402) over the oxide.

In another aspect, the forming the control gate can be further characterized as the control gate being directly on the oxide.

In another aspect, the method can further comprise forming a dielectric layer (702) on the oxide, wherein the step of forming the control gate is further characterized by the control gate being over the dielectric layer.

In another aspect, the method can further comprise forming a select gate structure (106) of silicon having a first sidewall prior to the step of growing the oxide layer, wherein the step of growing the oxide layer can be further characterized by growing the oxide layer on the first sidewall of the select gate structure; and the step of forming the control gate can be further characterized by the control gate being adjacent to the first sidewall of the select gate structure.

In another aspect, the step of forming the silicon nanocrystals can result in a median spacing between adjacent silicon nanocrystals being less than a thickness of the oxide layer; and the step of partially growing oxide on the nanocrystals can result in the median spacing between adjacent nanocrystals being more than a median distance from lowest surface of the silicon nanocrystals to the substrate.

In still further embodiments, a method of forming a split gate non-volatile memory (NVM) cell structure (100) using a silicon substrate (102) can comprise forming a select gate structure (106) comprising polysilicon having a first side; applying heat and oxygen to form a thermal oxide layer (110) on a surface of the silicon substrate adjacent to the first side of the select gate structure and on the first side of the of the select gate structure; forming silicon nanocrystals (202) on the thermal oxide layer; applying heat and oxygen to oxidize a portion (302) of the nanocrystals; and after oxidizing a portion of the nanocrystals, forming a control gate (402) over the nanocrystals and adjacent to the first side of the select gate structure.

In another aspect, the forming the silicon nanocrystals can result in a median spacing between adjacent nanocrystals that is less than a thickness of the thermal oxide layer; and the applying heat and oxygen to oxidize a portion of the nanocrystals can result in a median height above a top surface of the substrate of the lower surface of the nanocrystals being less than a median spacing of the nanocrystals.

In another aspect, the method can further comprise depositing a dielectric layer (702) over the nanocrystals after applying heat and oxygen to oxidize a portion of the nanocrystals and before forming the control gate.

Because the apparatus implementing the present disclosure is, for the most part, composed of electronic components and circuits known to those skilled in the art, circuit details will not be explained in any greater extent than that considered necessary as illustrated above, for the understanding and appreciation of the underlying concepts of the present disclosure and in order not to obfuscate or distract from the teachings of the present disclosure.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Although the disclosure is described herein with reference to specific embodiments, various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to disclosures containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method of making a non-volatile memory (NVM) cell using a substrate having a top surface of silicon, comprising:
forming a select gate stack over the substrate;
growing a thermal oxide layer on the top surface of the substrate;
forming nanocrystals of silicon on the thermal oxide layer adjacent to a first side of the select gate stack;
partially oxidizing the nanocrystals to result in partially oxidized nanocrystals and further growing the thermal oxide layer;
forming a control gate over the partially oxidized nanocrystals;
forming a first doped region in the substrate adjacent to a first side of the control gate and a second doped region in the substrate adjacent to a second side of the select gate.

2. The method of claim 1, wherein the step of forming the select gate stack is further characterized by the select gate stack comprising polysilicon.

3. The method of claim 2, wherein the step of growing the thermal oxide layer is further characterizing as growing the thermal oxide on the polysilicon on the first side of the select gate.

4. The method of claim 3, wherein the step of forming the nanocrystals is further characterized by forming nanocrystals on the thermal oxide on the first side of the select gate.

5. The method of claim 4, further comprising forming sidewall spacers adjacent to the second side of the select gate and the first side of the control gate.

6. The method of claim 1, wherein the step of forming the control gate is further characterized by the control gate being deposited directly on the partially oxidized nanocrystals.

7. The method of claim 6, wherein the step of forming the control gate is further characterized by the control gate comprising polysilicon.

8. The method of claim 1, further comprising depositing a dielectric layer on the partially oxidized nanocrystals prior to forming the control gate, wherein the forming the control gate is further characterized by being over the dielectric layer.

9. The method of claim 1, wherein the step of forming the control gate comprises:
depositing a conductive layer over the partially oxidized nanocrystals; and
patterning the conductive layer to form the first side of the control gate and to form a second side of the control gate over the select gate.

10. The method of claim 1, wherein,
the step of forming the nanocrystals is further characterized by the nanocrystals having a median original diameter; and
the step of partially oxidizing the nanocrystals results in a reduction from the median original diameter of about one fourth.

11. The method of claim 1, wherein the step of forming the nanocrystals is further characterized by the median original diameter being about 16 nanometers.

12. The method of claim 1, wherein the step of partially oxidizing the nanocrystals results in sufficient oxide growth that the oxide growth of adjacent nanocrystals merges.

13. A method of forming a non-volatile memory (NVM) structure on a substrate having a silicon surface, comprising:
growing an oxide layer on the silicon surface;
forming silicon nanocrystals on the oxide layer;
partially growing oxide on the nanocrystals; and
forming a control gate over the oxide.

14. The method of claim 13, wherein the forming the control gate is further characterized as the control gate being directly on the oxide.

15. The method of claim 13, further comprising forming a dielectric layer on the oxide, wherein the step of forming the control gate is further characterized by the control gate being over the dielectric layer.

16. The method of claim 13, further comprising forming a select gate structure of silicon having a first sidewall prior to the step of growing the oxide layer, wherein:
the step of growing the oxide layer is further characterized by growing the oxide layer on the first sidewall of the select gate structure; and
the step of forming the control gate is further characterized by the control gate being adjacent to the first sidewall of the select gate structure.

17. The method of claim 13, wherein:
the step of forming the silicon nanocrystals results in a median spacing between adjacent silicon nanocrystals being less than a thickness of the oxide layer; and
the step of partially growing oxide on the nanocrystals results in the median spacing between adjacent nanocrystals being more than a median distance from lowest surface of the silicon nanocrystals to the substrate.

18. A method of forming a split gate non-volatile memory (NVM) cell structure using a silicon substrate, comprising:
forming a select gate structure comprising polysilicon having a first side;
applying heat and oxygen to form a thermal oxide layer on a surface of the silicon substrate adjacent to the first side of the select gate structure and on the first side of the of the select gate structure;
forming silicon nanocrystals on the thermal oxide layer;
applying heat and oxygen to oxidize a portion of the nanocrystals; and
after oxidizing a portion of the nanocrystals, forming a control gate over the nanocrystals and adjacent to the first side of the select gate structure.

19. The method of claim 18, wherein
the forming the silicon nanocrystals results in a median spacing between adjacent nanocrystals that is less than a thickness of the thermal oxide layer; and
the applying heat and oxygen to oxidize a portion of the nanocrystals results in a median height above a top surface of the substrate of the lower surface of the nanocrystals being less than a median spacing of the nanocrystals.

20. The method of claim 18, further comprising depositing a dielectric layer over the nanocrystals after applying heat and oxygen to oxidize a portion of the nanocrystals and before forming the control gate.
